(19) United States
(12) Patent Application Publication
(10) Pub. No.: US 2003/0015345 A1
(43) Pub. Date: Jan. 23, 2003

(54) Laminated base sheet for flexible printed circuit board

(76) Inventors: Hitoshi Arai, Ibaraki-ken (JP); Yoshitsugu Eguchi, Ibaraki-ken (JP)

Correspondence Address: WENDEROTH, LIND & PONACK, L.L.P., 2033 K STREET N. W., SUITE 800, WASHINGTON, DC, 20006-1021, US

(21) Appl. No.: 10/175,871

(22) Filed: Jun. 21, 2002

(30) Foreign Application Priority Data
Jun. 27, 2001 (JP) 2001-194891

(51) Int. Cl. H05K 1/00; H05K 1/03

(52) U.S. Cl. 174/256; 174/250; 174/257

(57) ABSTRACT

The invention discloses an improved base sheet for flexible printed circuit boards used in assemblage of compact-size electric or electronic instruments. The base sheet is a layered sheet body consisting of (a) a layer of an electrically insulating material having flexibility such as plastic resin films and (b) a copper foil of a specified thickness adhesively laminated to the insulating film (a) with intervention of (c) a thermosetting adhesive layer. Excellent processability of the base sheet to a printed circuit board having a finely patterned copper foil layer can be obtained when the surface of the copper foil (b) in contact with the thermosetting adhesive layer (c) has a surface roughness Rz not exceeding 3 μm and is provided with a surface treatment layer in which the content of nickel is in the range from 0.001 to 0.1 g/m².

### BACKGROUND OF THE INVENTION

The present invention relates to a novel laminated base sheet for flexible printed circuit boards. More particularly, the invention relates to a laminated base sheet comprising an electrically insulating flexible film or sheet and a metal foil laminated therewith as adhesively bonded directly or, preferably, with intervention of a layer of a thermosetting adhesive, which is processed to a flexible printed circuit board by patterning the metal foil into an electric circuit pattern.

Along with the rapid and extensive progress in the fields of electronic technologies in recent years, it is an outstanding trend that electronic instruments for information transmission and processing and livelihood applications are generally required to be more and more compact in size, lighter and lighter in weight and higher and higher in assemblage density of electronic devices built therein. Such a requirement can never be fulfilled without using numbers of flexible printed circuit boards in assemblage of the devices since flexible printed circuit boards, having flexibility to withstand repeated bending, are suitable for high-density mounting of devices even within very small spaces to serve as composite parts of the instrument functioning as wiring elements, cables and connectors.

Flexible printed circuit boards in general are manufactured by processing a base sheet for flexible printed circuit boards, which is a laminated sheet body consisting of an electrically insulating film or sheet such as a plastic resin film or sheet having flexibility and a metal foil, e.g., a copper foil, laminated with the insulating film, in most cases, with intervention of a thermosetting adhesive layer therebetween. Namely, the metal foil of the base sheet is pattern-wise removed by etching to leave a desired circuit pattern of the metal foil which is, if necessary, temporarily protected by attaching a releasable pressure-sensitive adhesive film.

Flexible printed circuit boards or base sheets therefor are required to be excellent in various properties including adhesive bondability of the resin film with the metal foil, bendability, folding endurance, solvent resistance, electrical properties, dimensional stability, long-term heat stability, flame retardancy and so on.

In relation to the base sheets processed into flexible printed circuit boards, the requirement for compactness of the size of the circuit boards is increasing year by year because flexible printed circuit boards are employed increasingly around liquid-crystal display panels or electronic devices such as IC chips are directly built in an electronic instrument. In order to comply with this trend, base sheets for flexible printed circuit boards are also required to meet the requirement, in addition to the above mentioned requirement for various properties, to have excellent processability into a miniaturized printed circuit boards as one of the important targets.

With regard to the above mentioned miniaturization of the flexible printed circuit boards, while the requirement several years ago relative to a parallel circuit line pattern, for example, was for a pitch of 100 μm with a 50 μm width for each of the lines and interline spaces, the requirement now is for a pitch of 80 μm or further 60 μm assuming that the line width and space width are equal each to the other.

In view of the above mentioned various requirements for flexible printed circuit boards or base sheets therefor, detailed investigations were undertaken heretofore for improvements relative to these regards but the investigations actually undertaken were concentrated to and around the studies on the types and thickness of the dry films as well as to the studies on the process parameters for circuit patterning such as patterning light exposure and development in the photolithographic patterning and etching process. Though not without some fruitful results, these investigations undertaken heretofore are now not considered to be sufficient in order to comply with the recent requirements for stabilization of so fine electric circuits and for further increased fineness of the circuit pattern.

### SUMMARY OF THE INVENTION

The present invention accordingly has an object, in view of the above described problems and disadvantages in the prior art, to provide a novel and improved base sheet for flexible printed circuit boards which can be easily processed into a flexible printed circuit board exhibiting excellent stability of the electric circuit even with extreme fineness of the circuit pattern.

Thus, the base sheet for flexible printed circuit boards provided by the present invention is a laminated sheet body which comprises:

(a) a layer of an electrically insulating material having flexibility; and

(b) a foil of copper adhesively bonded to one of the surfaces of the insulating layer with intervention of

(c) a layer of a thermosetting adhesive,

in which the copper foil (b) has a thickness in the range from 5 to 18 μm and the surface thereof in contact the adhesive layer (c) has a surface roughness expressed by the Rz value not exceeding 3 μm and is provided with a surface treatment layer containing nickel in an amount not exceeding 0.2 g/m² or, preferably, in the range from 0.001 to 0.1 g/m².

### BRIEF DESCRIPTION OF THE DRAWING

FIG. 1 is a schematic illustration of the photomask pattern used in the preparation of the circuit pattern A for evaluation tests.

FIG. 2 is a schematic cross sectional view of the circuit pattern B with nickel plating for evaluation tests.

### DETAILED DESCRIPTION OF THE PREFERRED EMBODIMENTS

While, generally, a base sheet for flexible printed circuit boards has a three layered structure consisting of a flexible film of an electrically insulating material such as a plastic resin film, a copper foil laminated therewith and a thermosetting adhesive layer intervening between the insulating film and the copper foil, a two-layered structure of the so-called cast type consisting of an insulating film and a copper foil bonded together by casting or a two-layered structure of the so-called plating type consisting of an insulating film and a copper layer formed by plating, the subject matter of the present invention is limited to the three-layered base sheet and the cast-type two-layered base sheet excluding the plating-type structure.

The electrically insulating film (a) is a film of a plastic resin such as polyamide resins, polyimide resins, polyester resins, poly-parabanic acid resins, polyphenylene sulfide resins, Aramid resins and the like, though not particularly limitative thereto, of which polyimide resin films are particularly preferable in respect of their excellent heat resistance, dimensional stability and mechanical properties.

The thickness of the insulating film is not particularly limitative depending on the particularly intended application of the printed circuit board but, in most cases, the thickness is selected in the range from 12.5 to 75 μm. If necessary, the insulating resin film can be subjected to a surface treatment, on a single surface or on both surfaces, such as the low-temperature plasma treatment, corona discharge treatment and sandblasting treatment for roughening.

It is usual that the surface of the copper foil coming into contact with the thermosetting adhesive layer (c) is provided with a surface treatment layer formed by conducting one or more steps of surface treatments including surface roughening treatmanet, barrier-forming treatment and rustproofing treatment, of which the surface roughening treatment is essential while these surface treatments are conducted electrically by dipping the copper foil in an aqueous solution of a salt of a metal such as nickel, copper, cobalt, zinc and the like, of which nickel salts are the most typical surface treatment agents, so that it is sometimes unavoidable that the surface treatment layer of the copper foil (b) contains nickel as a contaminant.

The above-mentioned three types of surface treatments have their respective effects. For example, the surface roughening treatment produces surface ruggedness of a few micrometers as raises abd recesses which serve as anchoring sites of the thermosetting adhesive to improve the adhesive bonding strength between the copper foil surface and the adhesive layer. The barrier layer formed by the above-mentioned barrier-forming treatment has a thickness of a few micrometers which serves to improve the adhesive bonding strength to the adhesive layer, heat resistance and solvent resistance. The rustproofing treatment of the copper foil surface is important naturally in respect of controlling the corrosion resistance and etching behavior of the copper foil.

The thermosetting adhesive composition for the adhesive layer (c) to bond the electrically insulating resin film (a) and the copper foil (b) is also not particularly limitative and various types of known thermosetting adhesive compositions used in conventional applications can be used for the purpose including those formulated, as the principal ingredients, with an epoxy/NBR resins, epoxy/acrylic resins, epoxy/polyester resins, epoxy/nylon resins, phenolic/NBR resins, phenolic/nylon resins and polyimide/epoxy resins. The thickness of the adhesive layer (c) is, though not particularly limitative, selected in the range usually from 5 to 20 μm or preferably from 5 to 15 μm as dried or as cured. This is because the flexible base sheet can be imparted with increased flexibility or bendability as the thickness of the thermosetting adhesive layer (c) is decreased if the adhesive bonding strength therewith or other properties of the base sheet are not adversely affected.

The thermosetting adhesive composition for the formation of the adhesive layer (c) is used usually in the form of a solution prepared by uniformly dissolving the above described resinous ingredients and other additives in an organic solvent exemplified, though not particularly limitative, by methyl alcohol, ethyl alcohol, isopropyl alcohol, acetone, methylethyl ketone, toluene, trichloroethylene, 1,4-dioxane, 1,3-dioxane, dioxolane and others either singly or as a mixture of two kinds or more.

The thermosetting adhesive composition in the form of a solution used in the preparation of the inventive base sheet is prepared to have a solid content in the range from 20 to 45% by weight or, preferably, from 25 to 40% by weight. When the solid content of the adhesive solution is too high naturally with an undue increase in the viscosity of the solution, the coating workability of the adhesive composition is adversely affected due to incompatibility between the resinous ingredients and the organic solvent. When the solid content of the adhesive solution is too low, on the other hand, a difficulty is encountered in accomplishing good uniformity of the thickness of the adhesive layer if not to mention the economical disadvantage and the environmental problems of pollution due to a large volume of the solvent vapor emission.

It is of course optional according to need that the thermosetting adhesive composition is compounded with a variety of additives including curing agents and/or accelerators, flame retardant agents, such as halogenated organic compounds, antimony trioxide, aluminum hydroxide and silicon dioxide, and antioxidants each in a limited amount. The adhesive composition can be prepared by uniformly blending the above described base ingredients and optional additives in a suitable blending machine such as pot mills, ball mills, roller mills, homogenizers, supermills and the like.

The copper foil as the layer (b) of the inventive base sheet for flexible printed circuit boards should have a thickness in the range from 5 to 18 μm and the surface thereof facing the insulating resinous film (a) with intervention of the adhesive layer (c) should have a surface roughness Rz not exceeding 3 μm. This surface is also provided with a surface-treatment layer containing nickel in a density not exceeding 0.2 g/m² or, desirably, in the range from 0.001 to 0.1 g/m². The copper foil can be any of electrolytic copper foils and rolled copper foils although electrolytic copper foils are preferred in view of the low availability of a rolled copper foil having a thickness smaller than 12 μm in addition to the advantages of the electrolytic copper foils in respects of surface characteristics, reliability and costs.

The copper foil to form the layer (b) of the inventive base sheet must satisfy all of the above mentioned requirements for the thickness, surface roughness and content of nickel in the surface treatment layer because these factors are each an important factor ruling the workability in the fine patterning works of the copper foil to form a finely patterned copper foil for an electric circuit. In particular, the thickness of the copper foil is deeply correlated to the fine patterning workability and it is a general trend that the patterning workability of the copper foil is improved as the thickness thereof is decreased within the above specified range.

The requirement for the surface roughness Rz of the copper foil is important because, when the surface roughness Rz is too large, it is sometimes difficult to accomplish a fine circuit pattern of high accuracy with good reproducibility due to decreased versatility in setting of the etching conditions sometimes resulting in incomplete etching or overetching. In addition, when the surface roughness Rz of the copper foil is too large with unduly large ruggedness on the surface, it sometimes takes place that an electrolytic ingredient in the copper foil is eventually retained in the cavities or recesses formed by replicative transfer of the so large ruggedness onto the thermosetting adhesive layer (c) or into the insulating resinous film (a) to greatly decrease the electric properties of the base sheet prepared therewith.

As to the limitation in the content of nickel in the surface treatment layer, it should be noted that nickel is more resistant than copper against etching under usual etching conditions so that, when the content of nickel in the copper foils is too large, etching of the copper foils may eventually be incomplete to give a cross sectional profile of the patterned copper foil layer with trailing skirts naturally decreasing the effective width of the insulating gap space between the patterned lines of the copper foil to greatly decrease the interline insulation. The surface treatment by which the surface treatment layer is formed on the surface of the copper foil can be a roughening treatment, for example, by sandblasting, an electrolytic plating treatment or a rustproofing treatment, of which the roughening treatment is preferred.

As is mentioned before, the copper foil to form the layer (b) of the inventive base sheet should have a thickness in the range from 5 to 18 μm or, preferably, from 5 to 12 μm. Although a copper foil having a thickness smaller than 5 μm can hardly be obtained in the metal foil industry even as an electrolytic copper foil, a copper foil having a so small thickness is disadvantageous due to difficulty in handling sometimes leading to occurrence of folds and wrinkles. On the other hand, difficulties are encountered in the fine patterning works with a copper foil having a too large thickness.

The copper foil should have a surface roughness Rz not exceeding 3 μm or, preferably, not exceeding 2 μm. A base sheet prepared from a copper foil of a too large surface roughness Rz may suffer a difficulty in obtaining an extremely fine circuit pattern of the copper foil.

It is essential that the surface treatment, e.g., roughening treatment and rustproofing treatment, of the copper foil surface does introduce nickel in a distribution density not exceeding 0.2 g/m² or, desirably, not exceeding 0.1 g/m². If the copper foil surface is contaminated with nickel in a too high distribution density, it would eventually be the case in etching of the copper foil that a part of the nickel remains unremoved by etching adversely decreasing the interline insulation of the circuit pattern resulting in occurrence of trailing skirts in the cross sectional profile of the fine circuit pattern formed by etching or plating to give rise to a difficulty in fine circuit patterning of the copper foil and a decrease in the electric properties of the flexible printed circuit board.

Following is a description of the procedure for the preparation of the base sheet according to the present invention. In the first place, an adhesive solution of an appropriate concentration is prepared by diluting a separately prepared thermosetting adhesive composition with an organic solvent and an electrically insulating plastic resin film in a roll is rolled out and uniformly coated with the above prepared adhesive solution by using a suitable coating machine such as a reverse roller coater and the like. The thus coated continuous-length plastic resin film is continuously introduced into an in-line drier oven and heated there at 40 to 160° C. for 2 to 20 minutes to effect evaporation of the organic solvent leaving the adhesive layer in a semicured state followed by lamination of the thus adhesive-coated resin film with a copper foil by passing through a roller laminater at 40 to 200° C. under a linear roller pressure of 2 to 200 N/cm to give a laminated sheet with the cured adhesive layer in-between. The thus obtained laminated sheet is then preferably subjected to a post-curing heat treatment at 100 to 200° C. for 1 to 10 hours to effect more complete curing of the adhesive composition. The thickness of the adhesive layer in the laminated sheet is in the range from 5 to 20 μm as dried.

In the following, the base sheet for flexible printed circuit boards according to the present invention is illustrated in more detail by way of Examples and Comparative Examples which, however, never limit the scope of the invention in any way.

In each of the Examples and Comparative Examples given below, the base sheet for flexible printed circuit boards prepared there was subjected to evaluation tests in the following manner.

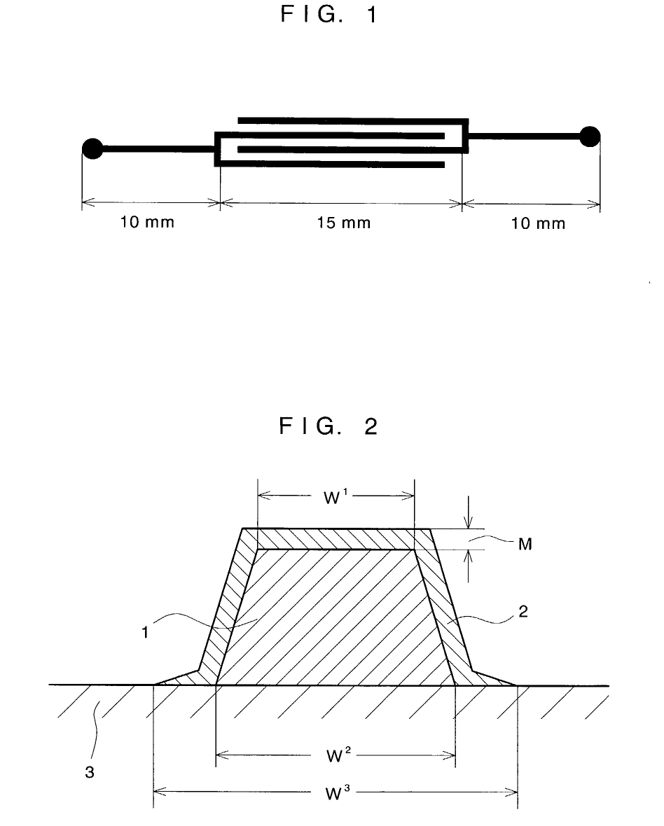

Sample preparation for evaluation of finely patterned circuit: A base sheet for flexible printed circuit boards prepared as described below was laminated on the copper foil with an ultraviolet-curable dry film of 24 μm thickness which was exposed to ultraviolet light through a photomask bearing a line-and-space pattern illustrated in FIG. 1 with a 30 μm width of each of the lines and interline gap spaces followed by a development treatment of the dry film layer for patterning the same. By using the thus patterned dry film layer as an etching resist, the copper foil was subjected to an etching treatment to form a patterned copper foil layer which served as a simulation electric circuit, referred to as the testing circuit A hereinafter, for the evaluation test. The testing circuit A was then plated with nickel in a plating thickness of 2 μm to give a nickel-plated circuit pattern, referred to as the testing circuit B hereinafter, having a generally trapezoidal cross sectional profile as shown in FIG. 2 and consisting of the patterned copper layer 1 and the plating layer 2 of nickel on the electrically insulating plastic resin film 3. The conditions for the etching treatment were as follows.

Apparatus: Model YCE-600WM, manufactured by Yoshitani Co.

Temperature: 45° C.

Pressure: 0.2 MPa

Duration: 60 seconds

Etching solution: aqueous iron(III) chloride solution, 45° Baumé

Circuit evaluation (a): Circuit factors F¹ and F² were calculated for the testing circuit B having a cross section of the patterned line illustrated in FIG. 2 from the values of M, W¹ , W² and W³ given there by using the following equations:

F¹=(W²−W¹)/W¹; and

F²=(W³−W¹−2M)/W¹,

in which W¹ is the top width of the patterned circuit line before nickel plating, W² is the bottom width of the patterned circuit line before nickel plating, W³ is the bottom width of the patterned circuit line after nickel plating and M is the thickness of the nickel plating layer at the top flat, Each of these circuit factors should desirably be as small as possible in order to ensure good orthogonality of the cross sectional profile of the patterned circuit line of the copper foil.

Circuit evaluation (b): Insulating resistance between the patterned lines was determined for the testing circuit B after washing for 10 minutes in a running stream of deionized water. Measurement was conducted according to JIS C6471 after application of a DC voltage of 500 volts for 1 minute between the insulated lines.

Circuit evaluation (c): Resistance against migration of copper between the patterned lines was examined for the testing circuit A in the following manner. Thus, a DC voltage of 500 volts was applied for 500 hours in an atmosphere of 100% relative humidity at 130° C. under a pressure of 130 kPa between the patterned lines of the testing circuit A after washing for 10 minutes in a running stream of deionized water to record occurrence or absence of short-circuiting between the initially insulated lines to record the results in two ratings of “good” and “poor” for absence and occurrence, respectively, of short-circuiting.

### EXAMPLE 1

A 200 mm square electrolytic copper foil of 12 μm thickness after a surface roughening treatment to have a surface roughness Rz of 0.8 μm and a barrier-forming treatment, of which the roughened surface layer contained 0.10 g/m² of nickel, was laminated on the roughened surface with a 200 mm square polyimide resin film of 25 μm thickness (Kapton 100V, a product by Toray Du Pont Co.) with intervention of a 15 μm thick layer of,an adhesive (E31, a product by Shin-Etsu Chemical Co.) by passing through a roller laminater at 100° C. under a linear roller pressure of 20 N/cm in a velocity of 2 meters/minute followed by a heat treatment first at 120° C. for 1 hour and then at 150° C. for 3 hours to effect curing of the adhesive layer. The thus obtained base sheet for flexible printed circuit boards was subjected to the evaluation tests in the above described testing procedures to give the results shown in Table 1 below.

### EXAMPLES 2 TO 4 AND COMPARATIVE EXAMPLES 1 TO 4

The procedures for the preparation of a base sheet for flexible printed circuit boards and for the evaluation tests in each of these Examples and Comparative Examples were substantially the same as in Example 1 described above except that the thickness of the copper foil, the surface roughness Rz of the roughened surface of the copper foil and the content of nickel in the surface treatment layer of the copper foil were as shown in Table 1. The results of the evaluation tests were sunnarized in Table 1.

TABLE 1

| | copper foil | | | | | | |
|---|---|---|---|---|---|---|---|
| | | surface | content of | circuit factor | | interline | |
| | thickness, | roughness- | nickel, | % | | insulation | copper |
| | μm | Rz, μm | g/m² | F¹ | F² | ohm | migration |
| Example | | | | | | | |
| 1 | 12 | 0.8 | 0.10 | 4.8 | 21.8 | 5 × 10¹² | good |
| 2 | 12 | 1.9 | 0.03 | 8.5 | 18.1 | 6 × 10¹² | good |
| 3 | 9 | 2.7 | 0.01 | 10.1 | 15.2 | 8 × 10¹² | good |
| 4 | 9 | 1.8 | 0.02 | 6.1 | 12.8 | 1 × 10¹³ | good |

Comparative
Example

| | | | | | | | |
|---|---|---|---|---|---|---|---|
| 1 | 9 | 4.9 | 0.03 | 24.0 | 38.0 | 3 × 10¹¹ | good |
| 2 | 12 | 8.5 | 0.00 | 30.0 | 34.0 | 1 × 10¹¹ | poor |
| 3 | 34 | 1.2 | 0.12 | 38.6 | 63.6 | 8 × 10¹¹ | good |
| 4 | 9 | 1.3 | 0.80 | 48.0 | 84.0 | 3 × 10¹¹ | poor |

What is claimed is:

1. A base sheet for flexible printed circuit boards which is an integral layered sheet body comprising:
(a) a film of an electrically insulating material having flexibility; and
(b) a foil of copper having a thickness in the range from 5 to 18 μm and adhesively bonded to a surface of the film of an electrically insulating material (a) with intervention of (c) a layer of a thermosetting adhesive,
the surface of the copper foil (b) in contact with the thermosetting adhesive layer (c) having a surface roughness Rz not exceeding 3 μm and being provided with a surface treatment layer in which the content of nickel does not exceed 0.2 g/m².

2. The base sheet for flexible printed circuit boards as claimed in claim 1 in which the content of nickel in the surface treatment layer of the copper foil (b) is in the range from 0.001 to 0.1 g/m².

3. The base sheet for flexible printed circuit boards as claimed in claim 1 in which the film of an electrically insulating material (a) having flexibility is a film of a polyimide resin.

4. The base sheet for flexible printed circuit boards as claimed in claim 1 in which the copper foil (b) has a thickness in the range from 5 to12 μm.

5. The base sheet for flexible printed circuit boards as claimed in claim 1 in which the thermosetting adhesive layer (c) has a thickness in the range from 5 to 20 μm.

6. The base sheet for flexible printed circuit boards as claimed in claim 1 in which the surface treatment layer of the copper foil (b) is a layer formed by a surface roughening treatment and a barrier-forming treatment treatment of the copper foil surface.

7. The base sheet for flexible printed circuit boards as claimed in claim 1 in which the electrically insulating film (a) has a thickness in the range from 12.5 to 75 μm.
